(19) United States
(12) Patent Application Publication
(10) Pub. No.: US 2025/0006583 A1
(43) Pub. Date: Jan. 2, 2025

(54) SEMICONDUCTOR PACKAGE WITH PRE-FORMED DIE CLIP AND LEAD FRAME

(71) Applicant: Tesla, Inc., Austin, TX (US)

(72) Inventors: William Thomas Chi, Fremont, CA (US); Utkarsh Raheja, Sunnyvale, CA (US); Sesha Sai Srikant Sarma Gandikota, San Jose, CA (US)

(21) Appl. No.: 18/754,008

(22) Filed: Jun. 25, 2024

Related U.S. Application Data
(60) Provisional application No. 63/510,569, filed on Jun. 27, 2023.

(51) Int. Cl. H01L 23/36; H01L 23/00; H01L 23/04; H01L 23/495; H01L 29/772

(52) U.S. Cl. CPC H01L 23/36; H01L 23/49517; H01L 23/49568; H01L 24/32; H01L 24/33; H01L 24/83; H01L 23/04; H01L 23/49562; H01L 29/772; H01L 2224/32245; H01L 2224/33181; H01L 2224/83007

(57) ABSTRACT

The present disclosure relates to a semiconductor package with a pre-formed die clip and lead frame. The semiconductor package includes a semiconductor die, a heat spreader on a first side of the semiconductor die, a lead frame on a second side of the semiconductor die, and a die clip positioned between the semiconductor die and a portion of the lead frame. The die clip and the lead frame are pre-joined by way of various connection points.

### CROSS-REFERENCE TO RELATED APPLICATIONS

This application claims the benefit of U.S. Provisional Patent Application No. 63/510,569, entitled “IMPROVED SEMICONDUCTOR DEVICE PACKAGES,” filed on Jun. 27, 2023, the disclosure of which is hereby incorporated by reference in its entirety and for all purposes. The present disclosure relates to U.S. application Ser. No. ______ [Attorney Docket: TSLA.789A2], filed on even date herewith, and titled “SEMICONDUCTOR PACKAGE WITH DIRECTIONAL LOCKING STRUCTURE,” the disclosure of which is hereby incorporated by reference in its entirety and for all purposes. The present disclosure relates to U.S. application Ser. No. ______ [Attorney Docket: TSLA.789A3], filed on even date herewith, and titled “SEMICONDUCTOR PACKAGE WITH NESTED LEAD STRUCTURE,” the disclosure of which is hereby incorporated by reference in its entirety and for all purposes.

### BACKGROUND

### Technical Field

This application relates to semiconductor device packages. In particular, some embodiments relate to semiconductor packages with a dual-sided heat dissipation structure and related manufacturing methods. Some embodiments relate to semiconductor packages with directional locking structures, having one or more slots on a lead frame of the semiconductor packages. Some embodiments relate to semiconductor packages with nested pinout structures, having drain leads on one side and device leads (such as gate lead and/or sensing lead) on another side.

### Description of Related Technology

Semiconductor devices are used in a wide variety of applications. In some applications, semiconductor devices can experience high electrical loads that can result in significant heating of the semiconductor device. There may be technical problems associated with high electrical loads, such as detrimental heating of the semiconductor device from the high load. In some applications, semiconductor devices can experience failure of interface connections between components of the semiconductor devices due to uneven thermal stress, such as uneven thermal expansion or contraction across the components of the semiconductor devices. There may be technical problems associated with interface connection failure during the operations of the semiconductor devices. In some applications, semiconductor devices can experience.

### SUMMARY

The innovations described in the claims each have several aspects, no single one of which is solely responsible for its desirable attributes. Without limiting the scope of the claims, some prominent features of this disclosure will now be briefly described.

One aspect of the present disclosure is a semiconductor package with a dual sided heat dissipation structure. The semiconductor package includes a semiconductor die having a first side and a second side, a heat spreader on the first side of the semiconductor die, a lead frame on the second side of the semiconductor die, and a die clip positioned between the semiconductor die and a portion of the lead frame. The second side is positioned opposite to the first side. The die clip is positioned between the semiconductor die and a portion of the lead frame. In addition, the die clip and the lead frame are joined at connection points.

In one embodiment, the die clip can include openings at the connection points.

In one embodiment, the lead frame can include a gate lead and a Kelvin source lead. A first connection point of the connection points can join the die clip and the gate lead, and a second connection point of the connection points can join the die clip and the Kelvin source lead.

In one embodiment, the semiconductor package can be free from solder between the lead frame and the die clip.

In one embodiment, the connection points can provide alignment points between the lead frame and the die clip for welding the die clip and the lead frame.

In one embodiment, the semiconductor die can include a field effect transistor. Additionally, the lead frame can include electrical contact points to terminals of the semiconductor die, and the terminals of the semiconductor die can include a source terminal, a gate terminal, and a Kelvin source terminal.

In one embodiment, a first side of the lead frame can include a plurality of leads. The plurality of leads can include two source leads connected to the source terminal of the semiconductor die, a gate lead connected to the gate terminal of the semiconductor die, and a Kelvin source lead connected to the Kelvin source terminal of the semiconductor die. The gate lead and the Kelvin source lead can be positioned between the two gate leads. In addition, a second side of the lead frame is positioned opposite to the first side of the lead frame. The lead frame can further include one or more drain leads electrically connected to the drain terminal of the semiconductor die. Furthermore, the semiconductor package can include a sensing lead on the first side of the lead frame, and the sensing lead can be positioned between the two source leads.

In one embodiment, the lead frame can include a lead, and at least a portion of the lead can be extended beyond the heat spreader can be flat.

In one embodiment, the semiconductor package can further include a thermistor die. In addition, the lead frame can include a thermistor lead electrically connected to a terminal of the thermistor die.

In one embodiment, the semiconductor package can further include a die attach solder positioned between the heat spreader and the first side of the semiconductor die.

In one embodiment, the heat spreader can be electrically connected to a drain terminal of the semiconductor die.

In one embodiment, the die clip can be positioned within a footprint of the lead frame.

Another aspect of the present disclosure is a method of assembling a semiconductor package. The method includes joining a die clip with a lead frame at a plurality of connection points and after the joining, soldering the die clip to a semiconductor die. the die clip and the lead frame are on an opposite side of the semiconductor die than a heat spreader after the soldering.

In one embodiment, the joining can include welding.

In one embodiment, the semiconductor die can include a field effect transistor, and the lead frame can include a gate lead and a Kelvin source lead.

In one embodiment, the die clip can include a plurality of openings at the connection points.

In one embodiment, the method can also include reflowing solder to connect the heat spreader and the semiconductor die prior to the soldering.

In one embodiment, the method can also include pre-molding the heat spreader prior to the soldering.

In one embodiment, the method can also include connecting a thermistor die to a lead of the lead frame.

Another aspect of the present disclosure is a semiconductor package. The semiconductor package includes a semiconductor die that includes a field effect transistor, molding material, and a conductive structure at least partly stacked with the semiconductor die. The conductive structure includes a plurality of slots positioned around a point of the semiconductor die. The plurality of slots is configured to equalize thermal stresses during an operation of the semiconductor die about the point of the semiconductor die. The thermal stresses are associated with coefficient of thermal expansion mismatches between the conductive structure and the molding material. At least a portion of the molding material is in contact with the conductive structure.

In one embodiment, the plurality of slots can be oriented in a radial pattern about the point of the semiconductor die.

In one embodiment, each slot of the plurality of slots can have a length in a direction extending away from the point and a width in a direction perpendicular to the length. The length can be longer than the width.

In one embodiment, the semiconductor package can also include a heat spreader on an opposite side of the semiconductor die than the conductive structure, that each slot of the plurality of slots can be positioned at least partly over the heat spreader.

In one embodiment, each slot of the plurality of slots can be positioned at least partly over the semiconductor die.

In one embodiment, the conductive structure can be a lead frame. Additionally, the lead frame can include a plurality of leads along a side of the semiconductor package that the plurality of leads can include two source leads, a sensing lead positioned between the two source leads, and a gate lead positioned between the two source leads. Furthermore, the semiconductor package can also include a die clip positioned between the semiconductor die and a portion of the lead frame that the die clip and the lead frame are joined at connection points.

In one embodiment, the conductive structure can be a die paddle.

Another aspect of the present disclosure is a semiconductor package. The semiconductor package includes a semiconductor die, molding material, and a lead frame at least partly stacked with the semiconductor die, including a plurality of slots positioned around a point of the semiconductor die. The plurality of slots is configured to equalize thermal stresses about the point of the semiconductor die, and at least a portion of the molding material is in contact with the lead frame.

In one embodiment, the plurality of slots can be oriented in a radial pattern about the point of the semiconductor die.

In one embodiment, at least one slot of the plurality of slots can have a rectangular shape.

In one embodiment, at least one slot of the plurality of slots can have a curved shape.

In one embodiment, each slot of the plurality of slots can include length in a direction extending away from the point and a width in a direction perpendicular to the length, such that the length can be longer than the width.

In one embodiment, the point can be a center point of the semiconductor package.

In one embodiment, the semiconductor package can also include a heat spreader on an opposite side of the semiconductor die than the lead frame. Each slot of the plurality of slots can be positioned at least partly over the heat spreader. In addition, at least one each of the plurality of slots can extend beyond the heat spreader.

In one embodiment, two or more slots of the plurality of slots can have different lengths.

In one embodiment, each slot of the plurality of slots can have a same width.

In one embodiment, the semiconductor die can include a field effect transistor. In addition, the lead frame can include a plurality of leads that can include two source leads electrically connected to a source of the field effect transistor, a gate lead electrically connected to a gate of the field effect transistor, and a sensing lead. Furthermore, the plurality of leads can be positioned on a first side of the lead frame, and the gate lead and the sensing lead can be positioned between the two source leads.

In one embodiment, the thermal stresses can be caused by coefficient of thermal expansion (CTE) mismatches between the lead frame and the molding material.

In one embodiment, the semiconductor package can also include a thermistor electrically connected to a sensing lead of the lead frame.

In one embodiment, the semiconductor package can also include a die coating material positioned between the die and the lead frame. The slots can be dimensioned to allow the die coating material to be injected therethrough during manufacture.

Another aspect of the present disclosure is a semiconductor package that includes a semiconductor die, including a field effect transistor, having a source, a gate, and a drain, and a plurality of leads. The plurality of leads includes two drain leads connected to the drain, two source leads connected to the source, a gate lead connected to the gate, and a sensing lead positioned between the two source leads. The gate lead is positioned between the two source leads. The two source leads, the gate lead, and the sensing lead are positioned on a first side of the semiconductor package that is opposite to a second side of the semiconductor package. The drain leads are positioned on the second side.

In one embodiment, the semiconductor package can also include a heat spreader positioned on an opposite side of the semiconductor die than a lead frame, and the lead frame can include the plurality of leads. In addition, the lead frame can include a plurality of slots positioned radially around a point. Furthermore, the semiconductor package can also include a die clip positioned between the semiconductor die and a portion of the lead frame, and the die clip and the lead frame can be joined at connection points.

In one embodiment, the plurality of leads can include a Kelvin source lead connected to a kelvin source terminal of the semiconductor die, such that the Kelvin source lead can be positioned between the two source leads on the first side.

In one embodiment, each lead of the plurality of leads can be a flat lead.

In one embodiment, the semiconductor package can also include a sensing die. In addition, the sensing lead can be connected to a terminal of the sensing die. In addition, the sensing die can be a thermistor die.

In one embodiment, the two drain leads can be located at same relative positions on the first side as the two source leads are located on the first side.

Another aspect of the present disclosure is a semiconductor assembly that includes a printed circuit board (PCB), a first semiconductor package on the PCB, and a second semiconductor package on the PCB. The first semiconductor package includes a first field effect transistor and a first plurality of leads, and the first plurality of leads includes two source leads and a gate lead positioned between the two source leads on a side of the first semiconductor package. The second semiconductor package includes a second field effect transistor and a second plurality of leads. The second plurality of leads includes two drain leads positioned on a side of the first semiconductor package. The first semiconductor package and the second semiconductor package are positioned such that the two drain leads are aligned with and electrically connected to the two source leads.

In one embodiment, the first plurality of leads can include a sensing lead positioned between the two source leads on the side of the first semiconductor package. In addition, the first semiconductor package can include a thermistor die electrically connected to the sensing lead.

In one embodiment, the first plurality of leads can include a Kelvin source lead positioned between the two source leads on the side of the first semiconductor package.

In one embodiment, the side of the second semiconductor package can be free from leads between the two drain leads.

In one embodiment, the side of the second semiconductor package can be free from leads in a region aligned with the gate lead.

In one embodiment, the two source leads can be flat leads, having flat portions that extend beyond the molding material of the first semiconductor package.

In one embodiment, the first semiconductor package and the second semiconductor packages can be two instances of a same semiconductor package design.

In one embodiment, each lead of the first and second plurality of leads can be a flat lead.

In one embodiment, the first semiconductor package can include a die paddle and a lead frame on opposite sides, and the lead frame can include the first plurality of leads.

In one embodiment, the first semiconductor package can include a lead frame that includes the first plurality of leads. The lead frame can include a plurality of slots positioned radially around a point.

For purposes of summarizing the disclosure, certain aspects, advantages, and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

These and other features, aspects, and advantages of the disclosure are described with reference to the drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A shows a cross section of an example device according to some embodiments.

FIG. 1B shows a cross-section of another example embodiment that uses an interstitial conductor.

FIG. 1C shows a cross-section of another example embodiment.

FIG. 1D shows another cross-section of another example embodiment.

FIG. 2A illustrates an exploded view of an example of a packaged IC device according to some embodiments.

FIG. 2B illustrates an exploded view of another example of a packaged IC device according to some embodiments.

FIG. 3 illustrates selected steps of a process for assembling a packaged IC device.

FIG. 4 illustrates an example combined lead frame structure that comprises a lead frame and a die clip.

FIGS. 5A and 5B illustrate bottom and top views, respectively, of an example packaged IC device according to some embodiments.

FIGS. 6A and 6B illustrate bottom and top views, respectively, of a pre-molded lead frame according to some embodiments.

FIG. 6C illustrates an example of a pre-molded lead frame after placement of a die clip solder, die clip, secondary die solder, and secondary die stacked atop a die clip.

FIG. 6D shows an example of a plurality of pre-molded lead frames.

FIG. 7 illustrates an assembly of a packaged IC device according to some embodiments.

FIG. 8A illustrates a packaged IC device with radially distributed slots according to some embodiments.

FIG. 8B illustrates a packaged IC device with distributed slots according to some embodiments.

FIG. 8C illustrates a packaged IC device with distributed slots according to some embodiments.

FIG. 8D illustrates an example of a lead frame with distributed slots according to some embodiments.

FIG. 8E illustrates an example of a lead frame with distributed slots according to some embodiments.

FIG. 8F illustrates an example of a lead frame with distributed circular slots according to some embodiments.

FIG. 8G illustrates an example of a lead frame with radially distributed spiral slots according to some embodiments.

FIG. 9 illustrates a minimalistic pinout example according to some embodiments.

FIG. 10 illustrates an example of a “head to toe” arrangement of semiconductor devices according to some embodiments.

FIG. 11 illustrates an example of a surface mount packaged IC device according to some embodiments.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. The headings provided herein are for convenience only and do not necessarily affect the scope or meaning of the claims.

### Introduction

Electronic components containing one or more integrated circuit (IC) dies can be deployed in a wide variety of applications. For example, such components can form part of a power electronics system. In some cases, such power electronics systems can be used to provide power for a heating, ventilation, and air conditioning (HVAC) system, an electric vehicle, and so forth. For example, in an electric vehicle, such systems can be used to convert alternating current to direct current for charging, from direct current to alternating current, or direct current at a first voltage to direct current at a second, different voltage to provide power output. Power electronics systems can also be used as part of a stationary energy storage system, such as a system for storing solar energy, or for other applications where there is a need for power delivery. A power electronics system can be used, for example, to convert direct current from a solar panel or battery to alternating current. In some cases, such power electronics systems can be used in utility applications, such as a grid-tie inverter that converts direct current to alternating current for insertion into an electrical power grid. These are merely examples, and there can be many other applications for such systems. In some cases, components of such systems can comprise diode switches, field effect transistors (FETs) such as metal-oxide-semiconductor field effect transistors (MOSFETs) (e.g., GaN MOSFETs), insulated-gate bipolar transistors (IGBTs), other bipolar transistors, the like, or any suitable combination thereof. In certain applications, such switches can be included in an inverter that converts a direct current (DC) voltage to an alternating current (AC) voltage. These components can have significant heat output when operational.

Thermal management can be provided via the use of relatively large lead frames, die paddles, heat spreaders, and so forth. Multiple reflow steps may be used during manufacturing, and components can shift during assembly. Misalignments can result in devices that experience reduced performance and/or shorter lifespans, or even devices that fail to function.

Power electronics systems can produce significant amounts of heat both under steady state load conditions and under power surge conditions. Heat can present significant problems. For example, excess heat can lead to reduced performance, reduced reliability, reduced lifespan, and so forth. For example, excess heat or large temperature fluctuations can lead to one or more of component damage, reduced lifetime, lower reliability, decreased performance, or the like. For example, excessive thermal stresses can weaken solder joints and/or damage semiconductor components. Illustratively, a substrate (or a frame that implements IC) of the power electronics systems can have a different coefficient of thermal expansion (CTE) in different portions of the substrate. These mismatch of CTE across the substrate can generate one or more concentrated thermal stress portions that cause mechanical strain on the substrate, such mechanical strain can cause delamination of the components implemented on the substrate. During operation, for instance, specific areas of the electrical component's substrate may experience concentrated thermal stresses, leading to differential expansion or contraction compared to other areas. Such concentrated thermal stress due to the mismatched CTE may cause disassembling the electrical component from the substrate. In some applications, power surge loads can result in rapid temperature rises. High power surge loads can be encountered in various applications, for example, when starting portable compressors, HVAC systems, refrigeration systems, electric motors, or the like.

Thermal considerations can conflict with other design considerations. For example, by having components very close together, higher switching speeds can be achieved. However, locating components close together can present challenges for managing temperatures.

Assembling power electronics components can also present several challenges. For example, there can be high power connections and low power connections (e.g., for use in temperature sensing, gate control, and so forth) that can be treated differently. For example, a lead frame can be used for high power connections, and a die clip can be used for low power connections. A die clip can be a conductor placed on top of other components requiring electrical or thermal connection or both.

This disclosure provides technical solutions to address one or more of the aforementioned technical challenges and/or one or more other technical challenges. Any suitable combination of the principles and advantages of these technical solutions can be implemented together with each other in a packaged IC device.

Aspects of this disclosure provide interstitial conductors can be included between heat spreaders in packaged IC devices. These conductors can provide one or more of signal, drive, sense, or other connection(s) to die(s) positioned between heat spreaders. The interstitial conductors can connect for electrical function and/or assist assembly to reduce manufacturing steps. Die clips and lead frames can be pre-assembled. This can provide manufacturing advantages. In some aspects of this disclosure, semiconductor packages can include thermal stress management so that thermal expansion and/or contraction can be equalized about a center point or other point, such as a hot spot. This can be achieved by various slot patterns, such as radially oriented features around the center point or other points. In some aspects of this disclosure, semiconductor packages can have an aligned architecture, such that contacts of packaged IC devices can be located. For example, a plurality of packaged devices can have contacts aligned with each other. High power signals can propagate straight to an adjacent and/or abutting packaged IC device. Other lower connections (e.g., signal, sense, drive) can be nested or centralized to avoid a power conduction path.

Package Design with Interstitial Conductors

Aspects of this disclosure relate to semiconductor devices with interstitial conductors. In a power integrated circuit (IC), electrical contacts for carrying high voltages can be relatively large, for example, to mitigate resistive losses. However, large, bulky electrical conductors can take up a significant amount of space and can involve a significant amount of material, which can result in larger, more expensive devices. In some cases, signal, drive, sense, and other electrical contacts can be relatively small compared to those contacts carrying high voltages.

In some cases, an interstitial conductor can be used to make connections for signal, drive (e.g., gate drive), sense, and so forth. As described herein, in some cases, a manufacturing process can be simplified. In some embodiments, signal and/or sense conductors can be layered between other thermal and/or electrical conductors. Leads can be shaped to contact a conductor alongside the die. For example, a lead can be shaped to connect to one or more of a bottom heat spreader, top heat spreader, die clip, and/or die paddle. In some cases, an interstitial conductor can be connected to an IC die. The IC die discussed herein are semiconductor die.

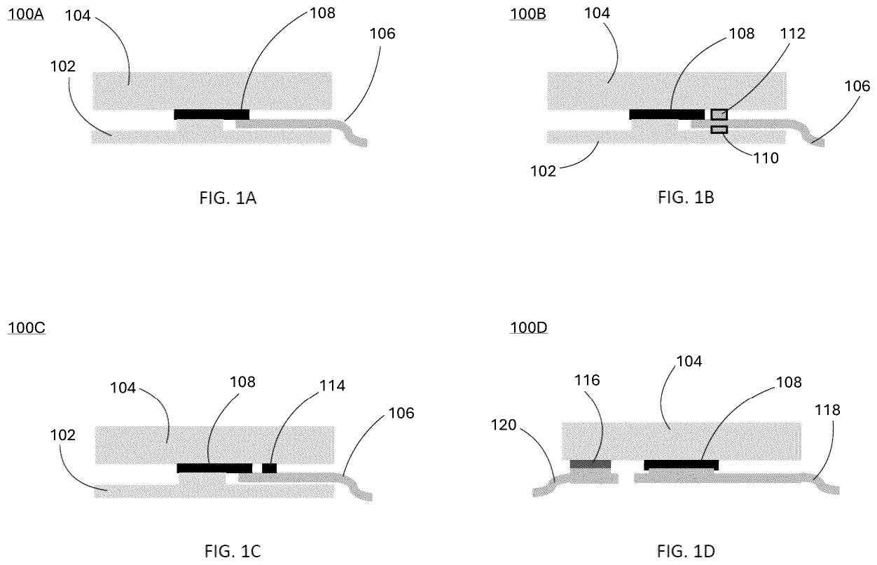

FIGS. 1A-1D illustrate the use of interstitial conductors in various example embodiments. FIG. 1A shows a cross section of an example device 100A according to some embodiments. In FIG. 1A, the device 100A can include a bottom heat spreader 102, a top heat spreader 104, an interstitial conductor 106, and IC die 108. The IC die 108 can be a semiconductor die. The IC die 108 can include one or more of the switches and/or transistors discussed herein. In some embodiments, the bottom heat spreader 102, the top heat spreader 104, or both can be used for thermal management. In some embodiments, the bottom heat spreader 102, the top heat spreader 104, or both can be used for electrically connecting to the IC die 108. In the example of FIG. 1A, the bottom heat spreader 102 and top heat spreader 104 can be used to provide electrical connections with the source and drain of the IC die 108. The interstitial conductor 106 can be used to provide signal and sense conductors. As shown in FIG. 1A, the interstitial conductor 106 can be electrically connected (e.g., directly electrically connected) to the IC die 108.

FIG. 1B shows a cross-section of another example embodiment of an example device 100B that uses an interstitial conductor. In FIG. 1B, the device 100B can include a bottom heat spreader 102, a top heat spreader 104, an interstitial conductor 106, and IC die 108. The interstitial conductor 106 can be connected to the top heat spreader 104 via the connection 112. The connection 112 can include, for example, solder. The interstitial conductor 106 can be connected to the bottom heat spreader 102 via the connection 110. The connection 110 can include, for example, solder. In some configurations, the interstitial conductor 106 can be connected to the bottom heat spreader 102 or the top heat spreader 104 but not both. Only one of the connections 110 or 112 can be included in such configurations. An arrangement such as the one depicted in FIG. 1B can be used for various purposes, such as to sense voltage or temperature.

FIG. 1C shows a cross-section of another example device 100C. In FIG. 1C, the device 100C can include a bottom heat spreader 102, top heat spreader 104, interstitial conductor 106, and IC die 108. The device can also include an additional component 114. The additional component 114 can be without limitation, for example, a thermistor for sensing internal temperature, another integrated circuit die, etc. The interstitial conductor 106 can have electrical contact with one or both of the IC die 108 and the additional component 114.

FIG. 1D shows another cross-section of another example device 100D. In FIG. 1D, the bottom heat spreader 102 is not present and has been replaced by conductor 120. The conductor 120 is electrically connected to the IC die 108 via the top heat spreader 104 and the element 116, and the conductor 118 can be electrically connected to the IC die 108. In some embodiments, the element 116 can be, for example, solder. In some embodiments, the element 116 can include a passive component, such as resistors, capacitors, inductors, conductive spacers, shims, and so forth.

Various possibilities exist for providing an interstitial conductor. For example, interstitial conductors can be embedded (e.g., partially embedded) in resin, mold compound, or the like. In some embodiments, an interstitial conductor can be exposed or partially exposed on a side of the device. In some embodiments, an interstitial conductor can be elevated. In some embodiments, an interstitial conductor can be flat.

Die clip and Lead Frame Pre-Assembly

In some embodiments, a die clip and lead frame can be used to provide various electrical connections. For example, a die clip, lead frame, or both can include source leads, gate leads, Kelvin source leads, thermistor leads, and so forth. In some embodiments, some leads (e.g., source leads) can be relatively large, while other leads (e.g., gate leads, sensing leads) can be relatively small. In some embodiments, a die clip can be used for smaller contacts. The use of a die clip can enable electrical separation between source leads and other leads (e.g., gate leads, sensing leads). However, the use of separate die clips and lead frames can present several challenges. For example, additional processing steps can be performed to affix the die clip to an IC die and to attach the die clip to the lead frame. These additional steps can provide an opportunity for manufacturing defects, which can reduce device yield.

In some approaches, the components of a die clip can be soldered, laser welded, or otherwise affixed together as part of a packaged IC device assembly process. A lead frame in any of the embodiments discussed below can be a top heat spreader in any suitable embodiments of FIGS. 1A to 1D. A die paddle in any of the embodiments discussed below can be a heat spreader in any suitable embodiments of FIGS. 1A to 1D. A die clip of any of the embodiments discussed below can be an interstitial conductor or heat spreader of any suitable embodiments of FIGS. 1A to 1D.

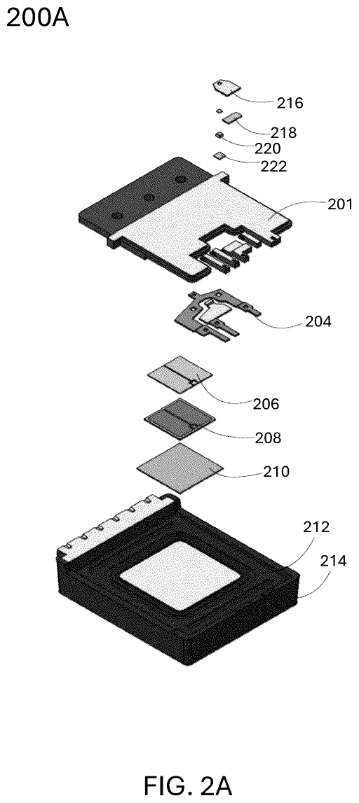

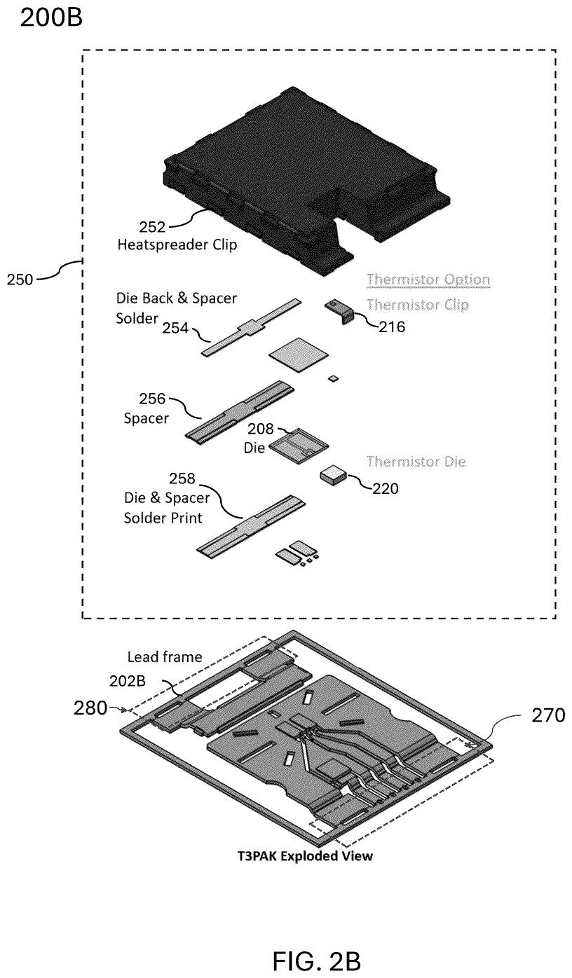

FIG. 2A illustrates an exploded view of an example of a packaged IC device 200A according to some embodiments. As shown in FIG. 2A, a packaged IC device can include a lead frame 201, a die clip 204, a die clip solder 206, an IC die 208, a die attach solder 210, a die paddle 212, and an enclosure 214. The IC die 208 can also be referred to as a semiconductor die. In some embodiments, a packaged IC device 200A can include additional components, for example, a thermistor die clip 216, a thermistor die clip solder 218, a thermistor die 220, and a thermistor solder 222. As described in more detail herein, in some embodiments, the lead frame 201 and die paddle 212 can be assembled prior to the assembly of the packaged IC device. In some embodiments, the die paddle 212 and enclosure 214 can be assembled prior to packaged IC device assembly.

In some examples, the lead frame 201 and the die paddle 212 of the packaged IC device 200A can be referred to as a dual sided heat dissipation structure. In some cases, the packaged IC device 200A can include the IC die 208, the die paddle 212, and the lead frame 201. The die paddle 212 can be formed with a thermally conductive material and is referred to as a heat spreader. In some embodiments, the lead frame 201 can be positioned on one side of the IC die 208 and the die paddle 212 can be positioned on the opposite side of the IC die 208. In some cases, the die paddle 212 is positioned within a footprint of the lead frame 201.

FIG. 2B illustrates an exploded view of parts of an example of a packaged IC device 200B according to some embodiments. As shown in FIG. 2B, a packaged semiconductor component 250 can be mounted on a lead frame 202A. In some embodiments, the lead frame 202A can provide electrical contacts for electrical connections with terminals of the IC die 208, such as drain, source, gate, and/or Kelvin source terminals. Furthermore, the lead frame 202A can also provide an electrical contact for an electrical connection with the thermistor 220.

As shown in FIG. 2B, the packaged semiconductor component 250 can include a heat spreader clip 252, a bonding layer 254 (e.g., a die back and spacer solder), a spacer 256, an IC die 208, a bonding layer 258 (e.g., a die back and spacer solder). In some examples, the bonding layers 254, 258 can be formed based on a pattern that can include multiple areas to provide electrical connections with corresponding die connection terminals (e.g., contact terminals), such as source (including Kelvin source), drain, and gate of the IC die 208. In some examples, the bonding layers 254, 258 can be formed by a conductive material, such as, without limitation, solder, conductive epoxy, or the like. In some embodiments, the packaged semiconductor component 250 can also include a thermistor die 220 and thermistor die clip 216.

The lead frame 202A can include various electrical contacts. The lead frame 202A can include conductive frames, such as lead frames of the packaged semiconductor component 250. These frames can be implemented with a pattern that can provide electrical contact with terminals of the IC die 208, such as drain, source, and gate (not shown in FIG. 2B) and/or terminals of the thermistor die 220.

Further referring to FIG. 2B, in some examples, field effect transistors (FETs) such as metal-oxide-semiconductor field effect transistors (MOSFETs) (e.g., GaN MOSFETs) can be implemented on the IC die 208. Thus, the IC die 208 can include terminals, such as the drain, source, Kelvin source, and gate. In some cases, the bonding layer 254 can be assembled (e.g., bonded) on the top of the IC die 208. In addition, the bonding layer 258 can be configured to bond the IC die 208 with the lead frame 202A. The bonding layers 254, 258 can be formed with a same type of molding material (e.g., conductive molding material) in certain applications.

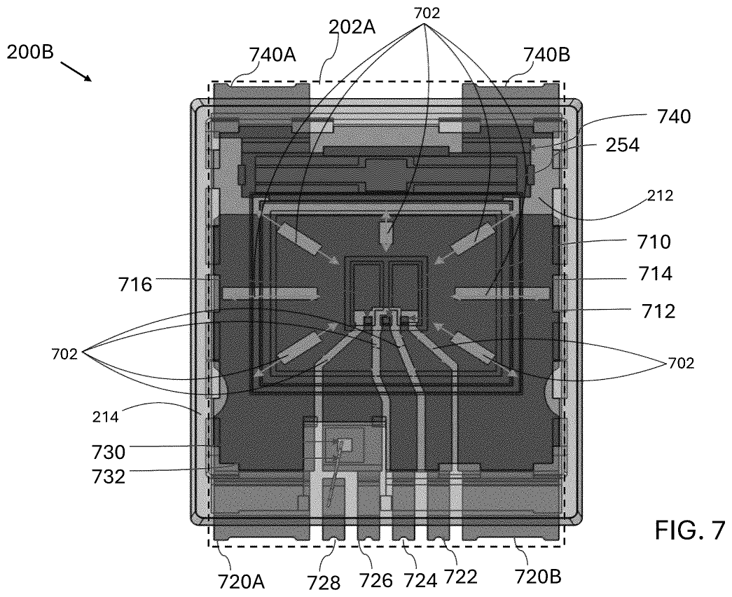

In some embodiments, the lead frame 202A can have flat leads, such as the flat leads 270 and 280 shown in FIG. 2B. For example, one side (e.g., bottom side) of the lead frame 202A can have the flat leads 270, and another side (e.g., upper side) of the lead frame 202A can have the flat leads 280. In some examples, the flat leads 270 and 280 extend outside of the heat spreader clip 252. For example, when the packaged semiconductor component 250 is assembled on top of the lead frame 202A, the flat leads 270 and 280 extend outside of the packaged semiconductor component 250. In some examples, the flat leads 270 can include source leads, a gate lead, a Kelvin source lead, and a sensing lead in accordance with embodiments disclosed herein. In certain applications, the sensing lead can be a temperature sensing lead that is electrically connected to the thermistor die 220. The flat leads 280 can include drain leads in accordance with embodiments disclosed herein. A detailed physical layout of the leads and the lead frame are provided in FIG. 7, for example.

In some embodiments, the flat leads 270 and 280 of the lead frame 202A can enable a thinner profile (e.g., low profile) for the packaged IC device 200B. In some examples, the flat lead 270 and 280 can serve as electrical contact points (e.g., terminals) for the packaged IC device 200B, where each lead of the flat leads have an appropriate thickness to facilitate the transfer of the generated signal or electrical power. For instance, the thickness of the flat leads 270 and 280 can be a minimum of 5 mil or 0.127 mm. In some examples, the flat leads can include a wettable flank.

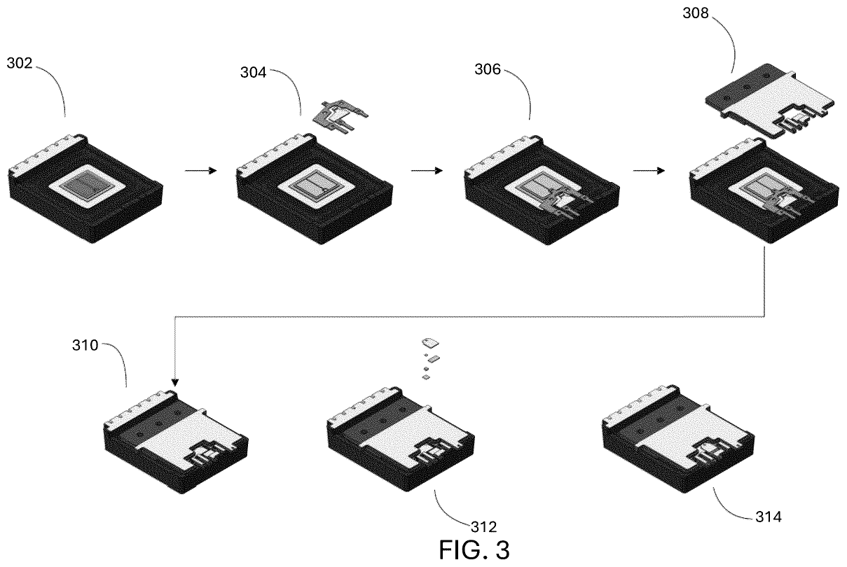

FIG. 3 illustrates an example semiconductor assembly corresponding to steps of assembling process of the packaged IC device 200A. At step 302, solder can be printed on a die paddle and a die can be placed on top of the solder. A first reflow process can be performed, for example by heating. After the first reflow process, solder can be printed and a die clip can be positioned in place (e.g., partially on top of the die) at step 304. At step 306, a second reflow process can be performed to affix the die clip to the die. At step 308, solder can be printed, and a lead frame can be positioned. At step 310, a third reflow process can be performed to affix the lead frame. In some cases, steps 312 and 314 can be carried out to include a thermistor assembly, which can result in one or more additional reflow steps.

The process illustrated in FIG. 3 can have several drawbacks. For example, there can be an opportunity for alignment errors and so forth each time an additional component is added. In some cases, components can shift during processing steps. For example, a component may shift during a reflow step. The number of reflow steps can impact solder and other material choices. For example, a reflow step that occurs first can preferably use a solder (e.g., solder paste) with a higher melting point than a solder used for a later reflow step, so that the first solder does not become fluid again during the later reflow step.

By reducing the number of steps to assemble a packaged IC device, several benefits can be realized. For example, assembly time can be reduced. As another example, yield can be improved as there are less opportunities for errors to occur. In some cases, components can be prepared prior to the final assembly process, and only known-good components can be used in the final assembly process. For example, in some embodiments, the lead frame 201 and die clip 204 can be affixed to one another in a separate process from the packaged IC device assembly process. Laser welding, ultrasonic welding, or other suitable joining methods can enable the combination of thin, fine structures that engage with the die (or other components) to be pre-coupled with other conductors of other thicknesses as desired (e.g., that provide source or drain connections). For multi-stacked assemblies, this can reduce handling and misalignments as components are stacked atop one another.

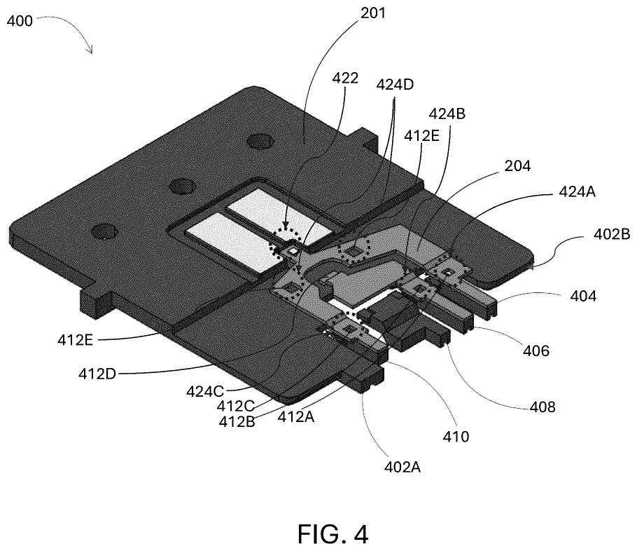

FIG. 4 illustrates an example combined lead frame structure 400 that comprises a lead frame 201 and a die clip 204. The die clip 204 can be affixed to the lead frame 201 in a variety of manners, for example, by welding (e.g., laser welding, ultrasonic welding, or any other suitable welding) or any other suitable joining methods. In some embodiments, the die clip 204 can include electrical contact points to the terminals of the IC die 208. In addition, the lead frame 201 can include a plurality of leads, and each lead is connected to one of the electrical contact points of the die clip 204. In some examples, as shown in FIG. 4, the lead frame 201 can include a source lead 402A or two source leads 402A and 402B. The lead frame 201 can also include a gate lead 404, a Kelvin source lead 406, and a thermistor lead 408. The thermistor lead 408 is an example of a sensing connection.

In some embodiments, the die clip 204 can be assembled with the lead frame 201. The die clip 204 can be connected to the electrical terminals of the IC die 208 at one or more contact points, such as contact point 422. The contact point 422 can be electrically connected to the terminals of the IC die 208. FIG. 4 is merely provided as an example embodiment, and the die clip 204 can have various contact points to electrically connect with terminals, such as drain, source, and gate terminals, and/or Kelvin source terminal of the IC die 208. The present disclosure does not necessarily limit the configuration (or layout or pattern) of the die clip 204.

Lead 410 may not extend out of a packaged IC device and may not be used for electrical connection. The Kelvin source lead 406 can step down and be welded to the lead frame 201 to sense the voltage of the lead frame 201. It will be appreciated that FIG. 4 is merely an example, and in practice, the number of leads can vary, and leads can be used for purposes in addition to or alternatively to the leads shown in FIG. 4.

In some embodiments, the lead frame 201 and die clip 204 can be pre-joined, for example, at connection points 412A-412E. The connection points 412A-412E can be, for example, laser-welded connections. Furthermore, the connection points 412A-412E can function as alignment points between the lead frame 201 and the die clip 204. By pre-joining the lead frame 201 and die clip 204, a manufacturing process can be improved, for example, by reducing the number of reflow steps. For example, the step 304 of FIG. 3 (the soldering process) and the reflow process of step 306 of FIG. 3 can be removed by pre-joining the lead frame 201 and die clip 204. When the lead frame 201 and the die clip 204 are pre-joined by welding, there can be no solder between the lead frame 201 and the die clip 204. Accordingly, a semiconductor package can be free from solder between the lead frame 201 and the die clip 204. After the lead frame 201 and the die clip 204 are joined, the die clip 204 can be soldered to the IC die 208. The lead frame 201 and the die clip 204 can both be soldered during the same reflow step.

The die clip 204 can comprise openings at the connection points 412A-412E. The openings can facilitate welding the die clip 204 and the lead frame 201. In FIG. 4, the die clip 204 includes a first opening 424A corresponding to the gate lead 404. The die clip 204 and the gate lead 404 can be joined at a first connection point 412A of the connection points 412A-412E as illustrated. The die clip 204 can include a second opening 424B corresponding to the Kevlin source lead 406. The die clip 204 and the Kevlin source lead 406 can be joined at a second connection point 412B of the connection points 412A-412E. The die clip 204 can include an opening 424C corresponding to a third connection point 412C for joining with the lead 410 and openings 424D corresponding to fourth and fifth connection points 412D-412E for joining with the source leads 402A and 402B, respectively. In some embodiments, a laser weld can be applied on the openings (for example, by using thinner welding material on top of each opening) at the connection points 412A-412E. In some applications, the welding can be along the sides or special weld tab shapes can be used to minimize weld distortion.

In addition, for multi-stacked assembly applications, pre-joining the lead frame 201 and the die clip 204 can reduce handling by fewer assembly steps and can reduce the risk of misalignment occurring with each level stacked on the assembly. In some embodiments, a pre-joined lead frame that has imperfections can be rejected and may not be used to make a device. A defective pre-joined lead frame can, in some embodiments, undergo a rework process to correct any issues before the pre-joined lead frame is used.

In some embodiments, one or more additional leads can extend (not shown in FIG. 4) from the source portion 402B of the lead frame 201. In such embodiments, the gate lead 404, the Kelvin source lead 406, the thermistor lead 408, and the lead 410 can be located between the two source leads.

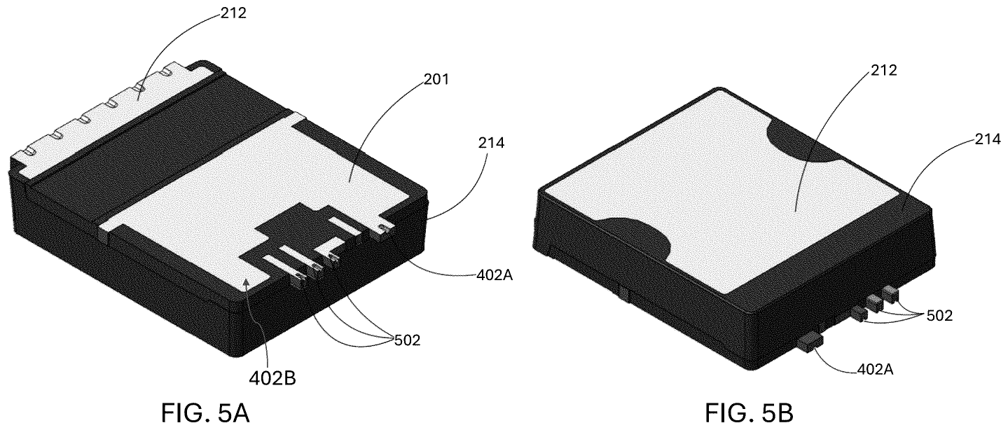

FIGS. 5A and 5B illustrate bottom and top views, respectively, of an example packaged IC device according to some embodiments. As shown in FIG. 5A, the packaged IC device can include lead frame 201, die paddle 212, enclosure 214, source lead 402, and leads 502. In some cases, the leads 402, 502 can extend outside of the enclosure 214. In some embodiments, the lead frame 201 can be at least partially exposed on the bottom surface of the packaged IC device, although in other embodiments, the lead frame 201 may not be exposed (e.g., only the source lead 402, rather than a larger portion of the lead frame 201, may be exposed). The packaged IC device can include leads 502, which include, for example, one or more thermistor leads, one or more gate leads, one or more Kelvin source leads, and so forth. Components of the packaged IC device can be disposed within enclosure 214. In some embodiments, an additional lead can extend (not shown in FIG. 5A) from the source portion 402B of the lead frame 201.

As shown in FIG. 5B, in some embodiments, the die paddle 212 can be at least partially exposed on a top surface of the packaged IC device. In some embodiments, the die paddle 212 may not be partially exposed. For example, the top surface can be completely encased by the enclosure 214. In some embodiments, the die paddle 212 can act as a heat spreader. In some embodiments, a separate heat spreader can be used. For example, in some embodiments, the die paddle 212 may not extend vertically to the top surface of the packaged IC device and a separate heat spreader can be placed on top of the die paddle 212 and can be in thermal communication with the die paddle 212.

In some conventional approaches to manufacturing packaged IC devices, electronic components can be assembled in earlier steps and, once assembly of the electronic components is complete, the electronic components can be encased (e.g., partially encased) in an enclosure. In some embodiments, however, it can be advantageous to at least partially form the enclosure prior to all the electronic components being assembled. For example, in some embodiments, a die paddle and enclosure can be formed prior to assembly of the various components of the packaged IC device. In some embodiments, a pre-molded die paddle can be partially over-molded, which can encapsulate high-voltage surfaces.

Pre-molding the die paddle and its associated enclosure can offer several advantages. For example, pre-molding can result in ledges or other inward or outward features, which can be used to hold other components in precise positions, elevations, or both. This can reduce defects that can arise from movement, shifting, tilting, sinking, etc., that can occur during manufacturing (e.g., during transport, during the placement of solder paste, when stacking subcomponents, during reflow steps, and so forth). In some embodiments, the pre-molded lead frame can act as a dam or cavity, which can help contain flowable encapsulants that can be used for various purposes, such as locally reducing stresses on the die, sealing (e.g., low durometer die encapsulants or “glob-top”). For example, a less rigid encapsulant can be used to shield some components from more rigid molding compound that can be used in later steps.

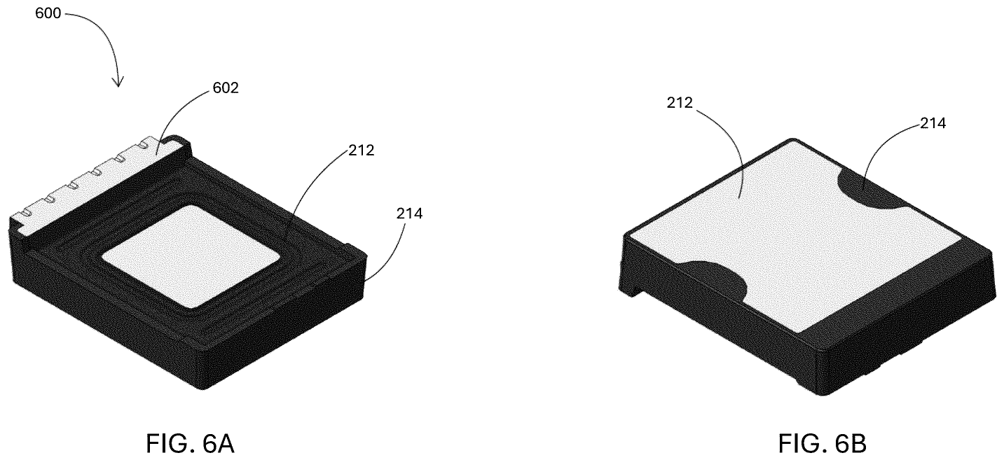

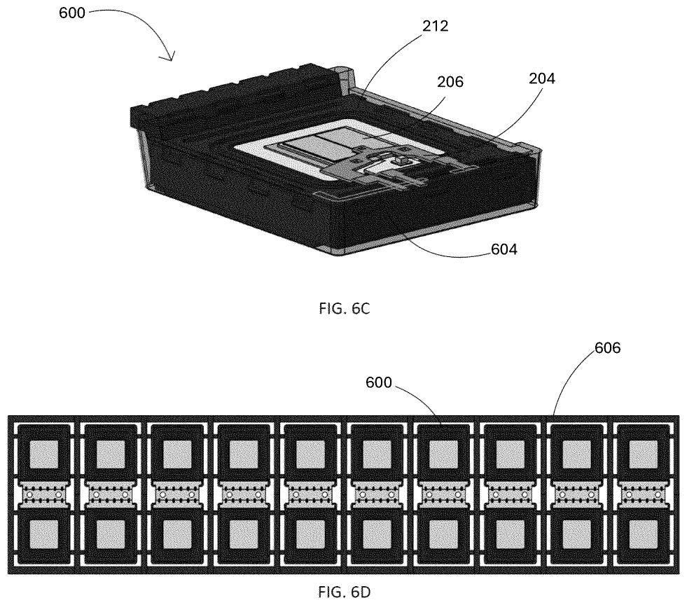

FIGS. 6A and 6B illustrate the bottom and top views, respectively, of a pre-molded die paddle 600 according to some embodiments. As shown in FIG. 6A, the pre-molded die paddle 600 can include a die paddle 212 and enclosure 214. The die paddle 212 can include drain contacts 602. In the illustrated example, a single large drain contact is depicted. However, it will be appreciated that there can be multiple drain contacts. In some embodiments, the die paddle 212 can include other contacts in addition or alternatively to the drain contacts 602. As shown in FIG. 6B, in some embodiments, the die paddle 212 can be partially exposed and can act as a heat spreader.

FIG. 6C illustrates an example of a pre-molded die paddle 600 after placement of a die clip 204 and die clip solder 206. As shown in FIG. 6C, the ledges 604 can support the die clip 204, which can help keep the die clip 204 in place and at a desired elevation.

FIG. 6D shows an example of a plurality of pre-molded die paddles. Each pre-molded die paddle 600 of the plurality of die paddles shown in FIG. 6D can be attached to a support frame 606. The support frame 606 can be used during manufacturing to facilitate transport, positioning, alignment, etc., of the pre-molded lead frames. The support frame 606 may itself comprise a mold resin channeling structure for resin injection into multiple mold cavities, commonly referred to as a runner system.

### Management of Thermal Stresses

Management of thermal stresses can be significant in semiconductor devices. Thermal stresses can be especially challenging in high power semiconductor devices, which may operate over a relatively wide temperature range. Uneven thermal stresses can lead to increased wear on a device, decreased lifespan, or even result in a non-functional device, for example if a die cracks, a solder connection breaks, and so forth. In some cases, mold-to-conductor delamination can occur as a result of thermal stresses.

In some embodiments, a lead frame and/or other structures such as mold-locking slots, conductor leads, and so forth can be designed to orient and shape directionally about the center of a die. In some embodiments, mechanical strains can be directed in a radial or centered fashion. In some embodiments, a geometrically neutral point or center point can be established, and thermal expansion and contraction can be balanced about this point. By spreading stresses evenly about a point, the risk of damage to a device as a result of thermal stresses can be reduced. In these embodiments, the lead frame can correspond to the lead frame 202A of the packaged IC device 200B. As illustrated in FIG. 2B, the packaged semiconductor component 250 can include at least the IC die 208 is bonded over the lead frame 202A. As disclosed herein, various slot patterns and/or structures can be implemented in the lead frame 202A. For illustrative purposes, FIG. 7 is described with reference to features of FIG. 2B.

FIG. 7 illustrates an example of the packaged IC device 200B of FIG. 2B according to some embodiments. The packaged IC device 200B includes a packaged semiconductor component 250 positioned on top of a conductive structure, such as the lead frame 202A by way of the bonding layer 258. In some embodiments, the IC die 208 included in the packaged semiconductor component 250 can be positioned or bonded on top of a center portion 710 of the lead frame 202A. The center portion 710 of the lead frame 202A can attach to the IC die 208. For example, the lead contacts points 712, 714, and 716 are electrically connected to a gate terminal, and a Kelvin source terminal, respectively, of the IC die 208.

The lead frame 202A can include a plurality of leads connected to terminals of the IC die 208. In some examples, source leads 720A, 720B are electrically connected to a source terminal of the IC die 208. A gate lead 724 of the plurality of leads is connected to the gate terminal of the IC die 208 via the lead point 714. In addition, a Kelvin source lead 726 of the plurality of leads is connected to the Kelvin source terminal of the IC die 208 via the lead point 716. In some examples, the lead frame 202A can include one or more additional die bonding portions positioned within the center portion 710. For example, a sensing die or another component configured to sense the electrical characteristics of the IC die, such as voltage, current, power, and the like, can be attached on the one of the one or more additional die bonding portions. For example, a sense lead 722 of the plurality of leads is connected to the sense terminal of a sensing die via the lead point 712. In some cases, a thermistor die can be electrically coupled with the lead frame 202A at the position 730. The thermistor die can is an example of a sensing die. The thermistor die can be configured to sense the temperature of the components, such as the packaged IC device, IC die 208, lead frame 202A, and/or any other components included in the packaged IC device. In some embodiments, the lead frame 202A can include one or more additional leads to electrically connect to terminal(s) of an additional IC die. For example, a thermistor lead 728 is electrically connected to the thermistor die via a bridge 732 (e.g., conductive wire or metal). In these embodiments, the thermistor lead 728 can be used to sense the temperature of components included in the packaged IC device. Accordingly, the thermistor lead 728 is an example of a sensing lead. The number and type of additional die and lead are merely illustrated as examples, and more than one additional die and lead can be used in certain applications.

The drain leads 740A, 740B can be electrically connected to a drain terminal of the IC die 208. For example, the heat spreader clip 252 illustrated in FIG. 2B can include a heat spreader layer under the top surface of the heat spreader clip 252. The heat spread layer can be formed with a conductive material. The heat spread layer can dissipate heat generated from the IC die 208. In addition, the heat spread layer can also be electrically connected with a drain terminal of the IC die 208. In some embodiments, the drain leads 740A, 740B can be connected to the heat spread layer. For example, an upper portion 740 of the lead frame 202A can be connected with the heat spread layer via the bonding layer 254, such that the bonding layer 254 is positioned between the upper portion 740 of the lead frame 202A and the heat spread layer.

As illustrated in FIG. 7, the lead frame 202A can include a plurality of slots 702 distributed across the lead frame 202A. For example, the plurality of slots 702 can be distributed around a location where a die would be placed on the lead frame. As illustrated, the slots are radially oriented around the center portion 710 of the lead frame 202A. The slots 702 can spread stresses evenly about a center point of the packaged IC device 200B. This can apply stresses from the coefficient of thermal expansion (CTE) mismatches evenly across the packaged IC device 200B. In some embodiments, a heat spreader can be positioned on an opposite side of the IC die 208 than the lead frame 202A. For example, if the IC die 208 is positioned on top of the lead frame 202A, the heat spreader can be positioned over the IC die 208. Also, if the IC die 208 is positioned under the lead frame 202A, the heat spreader can be positioned on top of the IC die 208. Further in these embodiments, each slot of the slots 702A-702K is positioned at least partly over or under the head spreader.

Alternatively or additionally, slots can be implemented on a die paddle 212 of a packaged IC device 200A of FIG. 2A. In some embodiments, the die paddle 212 and enclosure 214 of the packaged IC device 200A can be separate components. In some other embodiments, the die paddle 212 and enclosure 214 can be a single component, for example, the pre-molded die paddle 600 of FIGS. 6A-6D. The die paddle 212 can include a plurality of slots distributed about the die paddle 212. For example, the plurality of slots can be distributed around a location where a die would be placed on the die paddle 212, for example, the slots can be oriented around a hot spot on an IC die with a similar patterns of the plurality of slots 702 shown in FIG. 7 and/or other embodiments.

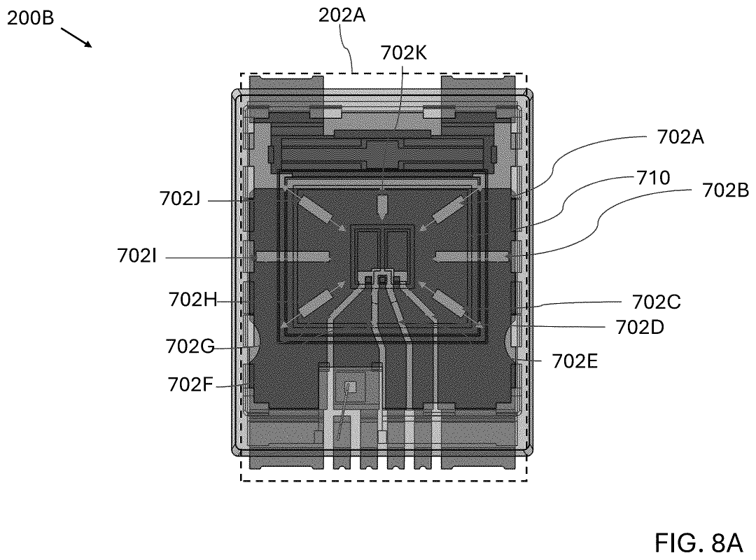

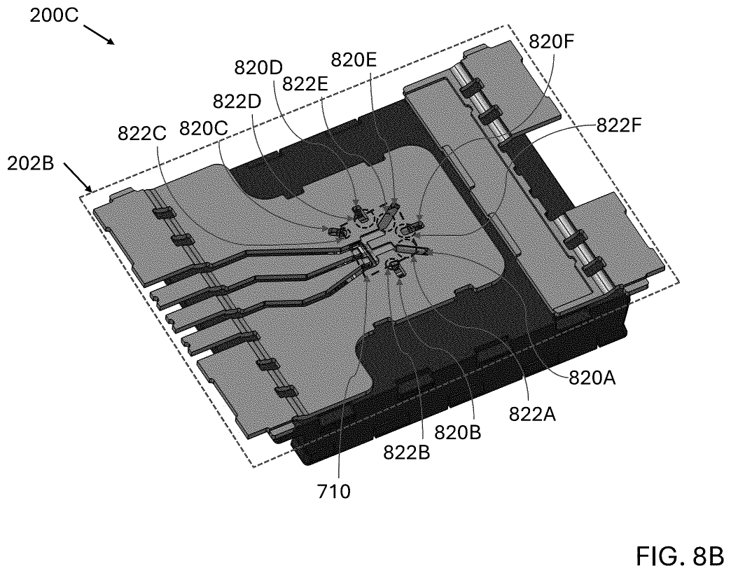

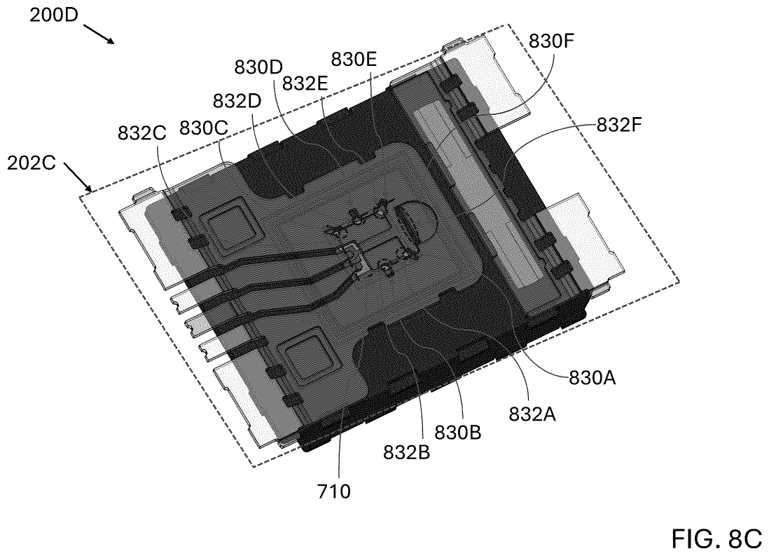

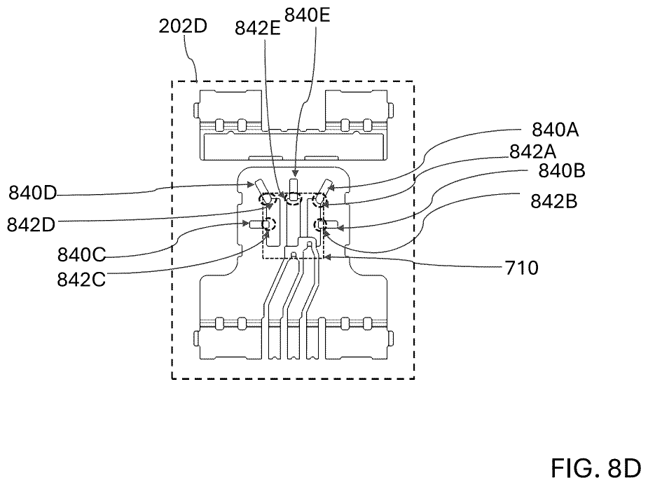

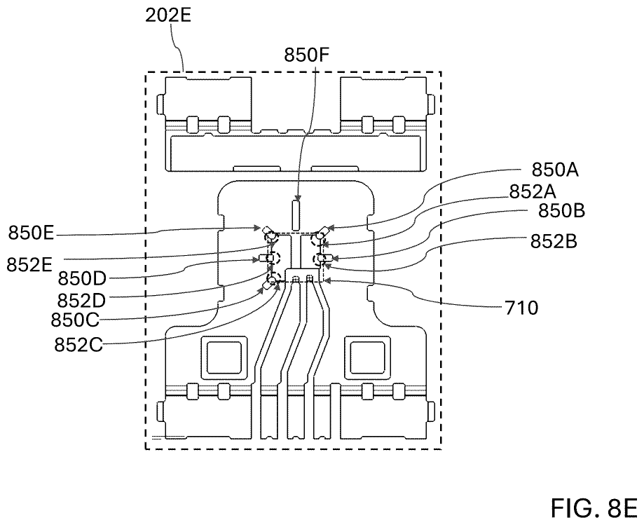

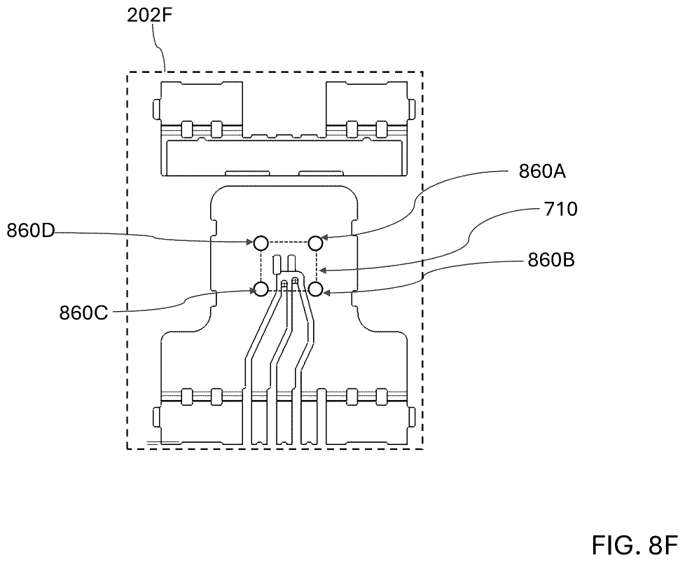

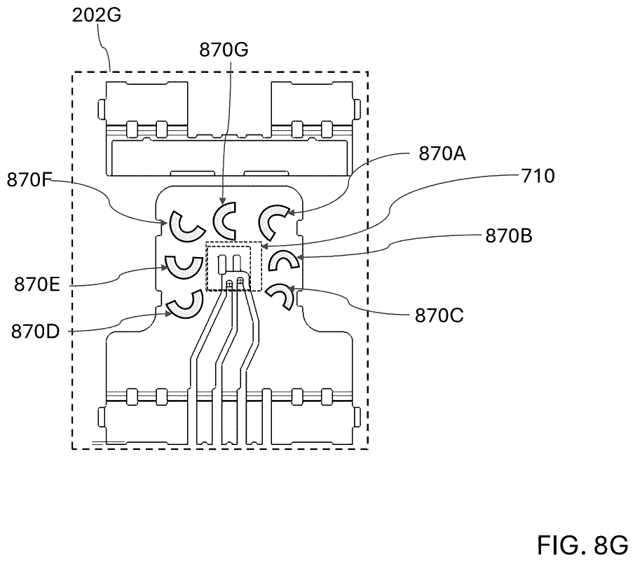

FIGS. 8A-8G illustrates various example patterns of slots implemented on a lead frame. In some embodiments, the pattern and each shape of the slots can be designed and/or optimized to effectively spread thermal stress on the lead frame. Lead frames 202A to 202G implementing example patterns are illustrated in FIGS. 8A to 8G, respectively. These various patterns and shape of the slots can be designed and/or optimized to evenly distribute the thermal stresses on the lead frame due to CTE mismatch without having a concentrated thermal stress on specific portion of the lead frame. Any suitable principles and advantages discussed with reference to FIGS. 8A to 8G can be implemented together with each other. For example, an embodiment can include one or more slots from one of these embodiments and one or more slots of another of these embodiments.

FIG. 8A illustrates a packaged IC device 200B with radially distributed slots 702A-702K in a lead frame 202A. FIG. 8A includes the same semiconductor package as FIG. 7. The lead frame 202A is also illustrated in FIG. 2B. In some embodiments, the slots 702A-702K are radially distributed surrounding the center portion 710, where the IC die 208 is positioned. In some embodiments, each slot of the slots 702A-702K can have a rectangular shape. In some examples, the length of each of the slots 702A-702K is greater than the width of each of the slots 702A-702K. In some cases, two or more of the slots 702A-702K can have a different length and/or width. In some embodiments, each slot of the slots 702A-702K has length in a direction extending away from a point, such as a center point, and a width is in a direction perpendicular to the length. In these embodiments, the length can be longer than the width for each of the slots.

FIG. 8B illustrates a packaged IC device 200C with a lead frame 202B. The lead frame 202B can include distributed slots 820A-820F, as illustrated in FIG. 8B. The slots 820A-820F have generally have an asterisk pattern. For the purpose of illustration, FIG. 8B shows a bottom view (a bottom view of the lead frame 202B) of the packaged IC device 200C. In some embodiments, the slots 820A-820F are distributed surrounding the center portion 710, where the IC die 208 is positioned in the opposite side of the center portion 710. In some embodiments, the slots 820A, 820C, and 820E can be adjacent to or abut respective corners of the center portion 710. In addition, the slots 820B, 820D, and 820F can extend beyond respective sides of the center portion 710. Each slot of the slots 820A-820F can have a rectangular shape. The length of each of the slots 820A-820F is greater than the width of each of the slots 820A-820F, as illustrated. In some cases, two or more of the slots 820A-820F can have a different length and/or width.

In some embodiments, as further illustrated in FIG. 8B, a portion of each of the slots 820A-820F can be located within the center portion 710 of a lead frame that is connected to an IC die. For example, portions 822A-822F of respective slots 820A-820F are located within the center portion 710. In some embodiments, each of the portions 822A-822F can be pathways for injecting a die coating material during manufacturing. For example, the die coating material can flow into the edges of the IC die 208. The die coating material flow can be capillary flow through the slots and around the die corners to adjacent edges. The die coating material can be a primer and configured to relieve thermal stress on the center portion 710 of the lead frame 202B. In addition, the die coating material can provide a CTE buffer layer on the lead frame 202B. In some embodiments, the die coating material has a low viscosity, so dripping the die coating material through the portions 822A-822F (e.g., through the bottom of the packaged IC device 200C (e.g., shown in FIG. 8B) can cause the die coating material to flow into the IC die 208 via the gravity or by capillary action. In some embodiments, the die corners along the edges of the IC die 208 can be the electrically or mechanically stressed areas, thus, placing the slots 820A-820F and the respective portions 822A-822F on these areas, for example, as shown in FIG. 8B can relieve the electrical or mechanical stress on the IC die 208. The die coating material can be any suitable commercial material, such as polyimide-silicone copolymer, and a person with skills in the semiconductor assembly industry can select the die coating material from the commercially available materials. The present disclosure does not limit the types of die coating material.

FIG. 8C illustrates a packaged IC device 200D with a lead frame 202C. The lead frame 202C can include distributed slots 830A-830F. FIG. 8C shows a bottom view of the packaged IC device 200D. In some embodiments, the slots 830A-830F are distributed surrounding the center portion 710, where the IC die 208 is positioned on the opposite side of the center portion 710. In some embodiments, the slots 830A, 830C, and 830E can be adjacent to or abut respective corners of the center portion 710. In addition, the slots 830B, 830D, and 830F can extend beyond three sides of the center portion 710. In some embodiments, at least one of the slots 830A-830F can have a semi-circular shape. For example, as illustrated in FIG. 8C, the slot 830F can have a semi-circular shape, and a portion 832F of the semi-circular shape can be located within the center portion 710. Part of slot 830F may not extend through the entire thickness of lead frame 202C and only a rectangular portion of the slot 830F may extend through the entire thickness of the lead frame 202C. In some examples, at least one of the slots 830A-830F can have a rectangular shape. For example, the slots 830A-830E can have a rectangular shape, and each rectangular slot of the slots 830A-830E can have a portion 832A-832E, respectively, positioned over the center portion 710. Any or all of the rectangular slots 830A-830E can have rounded corners. The length of each of the rectangular slots 830A-830E can be greater than the width of each of the slots 830A-830E as illustrated. In some cases, two or more of the slots 830A-830E can have a different length and/or width.

In some embodiments, an injection die coating material can be injected through the slots 830A-830F during manufacturing. For example, there can be a drip or jetted dispense of the die coating material during manufacture. Die coating can collect and funnel liquid die coating material between the lead frame 202C and clip structure to present the liquid die coating material to edges of the IC die. For example, the slot 830F can have an incline that funnels die through a rectangular portion that extends through the entire thickness of the lead frame 202C.

FIG. 8D illustrates an example of a lead frame 202D with distributed slots 840A-840E. The lead frame 202D can replace the lead frame 202A in the packaged IC device 200B, for example. The lead frame 202D can be implemented in any other suitable packaged IC device. The lead frame 202D includes slots 840A-840E. The slots 840A-840E of lead frame 202D can equalize radial expansion and/or contraction due to CTE mismatches about a point of a packaged IC device. Liquid die coating and/or adhesion promoter can be dispensed through the slots 840A-840E of lead frame 202D during manufacture. The slots 840A-840E can promote structural binding of a mold compound across the conductor of the lead frame 202D. The slots 840A to 840E can be implemented in accordance with any suitable principles and advantages disclosed herein. The slots 840A-840E can each have a generally rectangular shape. Corners of the slots 804A-8040E can be rounded. A portion 842A-842E of each of the slots 840A-840E, respectively, can overlap with a footprint of a semiconductor die.

FIG. 8E illustrates an example of a lead frame 202E with distributed slots 850A-850F. The lead frame 202E can be implemented in accordance with any suitable principles and advantages disclosed herein. For example, the lead frame 202E can replace the lead frame 202A in the packaged IC device 200B. The lead frame 202E includes slots 850A-850F distributed about of point of a packaged IC device. The slots 850A-850F have a different pattern than slots of other example embodiments. The slots 850A-850F can implement any suitable functionality of slots disclosed herein. Portions 852A-852E of respective slots 850A-850E can overlap with a footprint of an IC die.

FIG. 8F illustrates an example of a lead frame 202F with distributed slots 860A-860D. The lead frame 202F can be implemented in accordance with any suitable principles and advantages disclosed herein. For example, the lead frame 202E can replace the lead frame 202A in the packaged IC device 200B. The slots 860A-860D have a different pattern and shape than slots of other example embodiments. In some embodiments, the slots 860A-860D are positioned on each respective corner of a center portion 710 of the lead frame 202F on which the IC die 208 is positioned. In some embodiments, each of the slots 860A-860D can have a circular shape. In some examples, two or more of the slots 860A-860D can have a different diameter. In some embodiments, the diameter of two or more of the slots 860A-860D can have generally a same diameter.

FIG. 8G illustrates an example of a lead frame 202G with distributed slots 870A-870G. The lead frame 202G can be implemented in accordance with any suitable principles and advantages disclosed herein. For example, the lead frame 202E can replace the lead frame 202A in the packaged IC device 200B. As illustrated in FIG. 8G, the slots 870A-870G are radially distributed surrounding the center portion 710, where the IC die 208 is positioned. In some embodiments, each of the slots 870A-870G can be curved or arcuate. In some applications, a portion of one or more slots can be curved or arcuate. In some cases, two or more of the slots 870A-870G can have different shapes and/or sizes. In some embodiments, the shape and/or size of two or more of the slots 870A-870G can be the same.

### Power and Signaling

Integrated circuit packages are often integrated into larger circuits that may include many components. Arranging these components can be difficult as there can be a desire for thermal management, electrical connection management, or both. In some cases, the placement of various electronic components on a board (e.g., on a printed circuit) can be limited by technical specifications for thermal performance, electrical connection routing, or both. In some cases, the cost of a printed circuit board can be influenced by the components used on the circuit board and their arrangement. For example, more layers can be included for complex electrical routing. In some cases, it can be beneficial to place components close to each other, for example to reduce losses that can occur while signals propagate from one component to another.

In some embodiments, components can be arranged in series. For example, the drain of a first component can be connected to the source of a second component. In power electronics that use serially arranged components, it can be desirable to locate the drain of a first component as close as possible to the source of a second component. However, doing so can present several challenges. For example, while aligning sources and drains can be straightforward if those are the only electrical connections, in practice many electronic components have other connections, such as gates, Kelvin sources, thermistors, and so forth. One or more of the other connections can be implemented by an interstitial conductor positioned between heat spreaders, for example, as discussed with reference to FIGS. 1A to 1D. Alternatively or additionally, one or more of the other connections can be implemented by any of the die clips disclosed herein. According to some embodiments, a pocket can be provided that can enable close, head-to-toe linking of components so that sources and drains of adjacent components can be connected while other electrical connections (e.g., gate, sense pins, etc.) can be made while avoiding power conduction paths, including implementations where high-voltage potential differences exist between conductors and involve minimum separation or spacings.

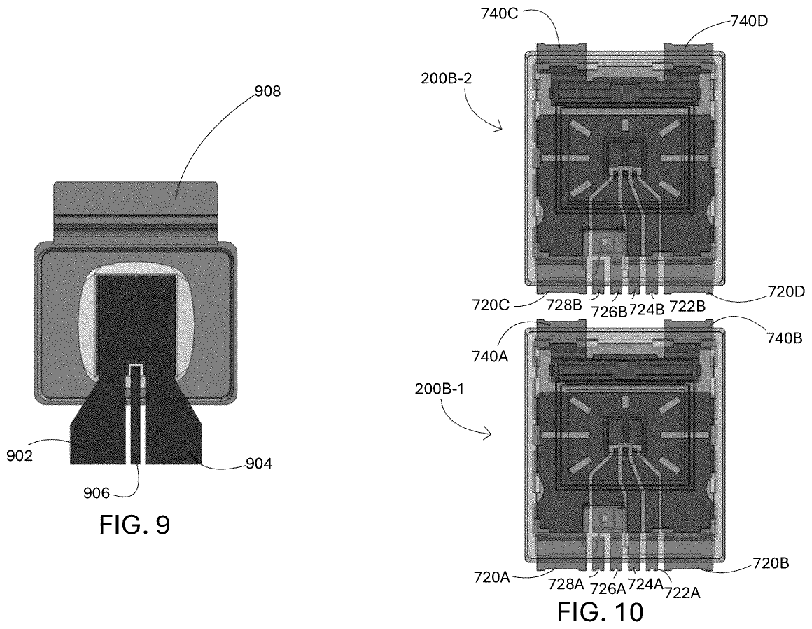

Although source and drain leads may be discussed below, any suitable principles and advantages discussed with reference to source and drain leads can be applied to emitter and collector leads or any other suitable sets of leads. The source and drain leads can be used with packaged IC devices with field effect transistors. Such field effect transistors can be included in power electronics devices, such as in inverters that generate an AC voltage from a DC voltage or vice versa. For illustrative purposes, FIGS. 9-10 may be described with reference to features of FIGS. 2B and 7.

FIG. 9 illustrates a minimalistic pinout example according to some embodiments. As shown in FIG. 9, a semiconductor device can have a first source lead 902, second source lead 904, and gate lead 906 disposed on one side of the semiconductor device. A drain lead 908 can be disposed on an opposite side of the device. In a serial arrangement, the drain lead 908 of a first semiconductor device can be connected to the first source lead 902 and second source lead 904 of a second semiconductor device. In some embodiments, only a single source lead may be present. In some embodiments, additional leads can be provided.

FIG. 10 illustrates an example of a head-to-toe arrangement of semiconductor devices according to some embodiments. In FIG. 10, a first packaged IC device 200B-1 and a second packaged IC device 200B-2 are arranged in a head-to-toe configuration. Each of the first packaged IC device 200B-1 and a second packaged IC device 200B-2 can be the packaged IC device 200B illustrated in FIGS. 2B and 7.

The first packaged IC device 200B-1 can include a first source lead 720A, second source lead 720B, gate lead 724A, Kelvin source lead 726A, thermistor lead 728A, and sense lead 722A. Disposed on an opposite side, the first device 200B-1 can have a first drain lead 740A and a second drain lead 740B. The second packaged IC device 200B-2 can have a first source lead 720C, second source lead 720D, gate lead 724B, Kelvin source lead 726B, thermistor lead 728B, and sense lead 722B disposed on a first side of the second packaged IC device 200B-2. The second packaged IC device 200B-2 can have a first drain lead 740A and second drain lead 740D disposed on a second side opposite the first side.

As shown in FIG. 10, the first drain lead 740A of the first packaged IC device 200B-1 can be electrically connected to the first source lead 720C of the second packaged IC device 200B-2 and the second drain lead 740B of the first packaged IC device 200B-1 can be electrically connected to the second source lead 720D of the second packaged IC device 200B-2. Electrical connection to the gate lead 724B, Kelvin source lead 726B, thermistor lead 728B, and sense lead 722B can be provided without crossing the power conduction paths defined by the locations of the sources and drains of the first packaged IC device 200B-1 and second packaged IC device 200B-2. The power conduction paths are provided by the PCB.

Although the first packaged IC device 200B-1 and the second packaged IC device 200B-2 of the packaged IC devices includes the thermistor lead 728A, 728B, Kelvin source lead 726A, 726B, and sense lead 722A, 722B in FIG. 10, one or more of these leads can be omitted in some other applications and/or one or more other leads can be included between source leads 720A and 720B in certain applications. For example, if a thermistor die is not implemented in the one or both of the first packaged IC device 200B-1 and the second packaged IC device 200B-2, the thermistor lead 728A, 728B can be omitted.

FIG. 10 also illustrates thermal management features to manage thermal explanation and/or contraction. In some embodiments, each of the first packaged IC device 200B-1 and a second packaged IC device 200B-2 can include any suitable in a conductive layer for thermal management features, such as any of the slot patterns illustrated in FIGS. 8A-8D. In some examples, the first packaged IC device 200B-1 and a second packaged IC device 200B-2 can have a same slot pattern as each other.

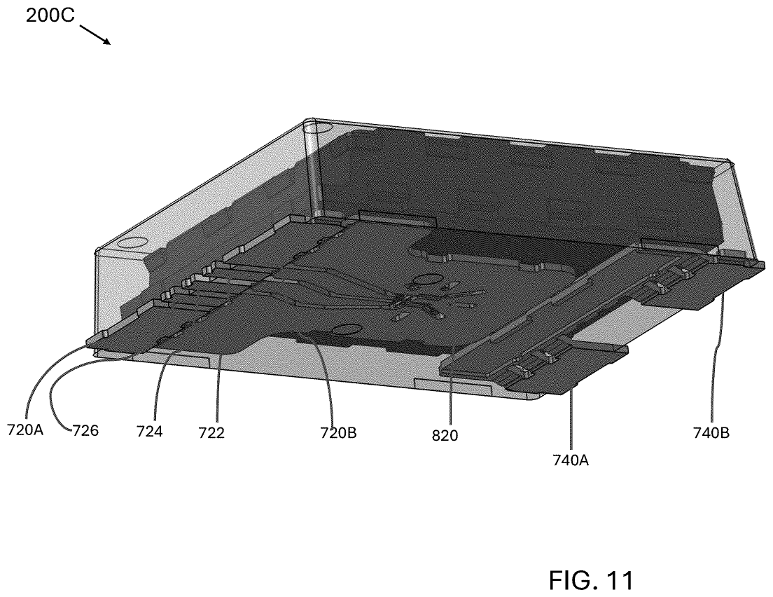

FIG. 11 illustrates an example of a packaged IC device according to an embodiment. FIG. 11 illustrates a view of the packaged IC device 202 with the lead frame 202B (shown in FIG. 8B). The packaged IC device illustrated in FIG. 11 can be implemented in accordance with any suitable principles and advantages disclosed herein. In some examples, the packaged IC device can be implemented as a surface mount device that can be mounted to a printed circuit board (not shown in FIG. 11) according to some embodiments. For example, in FIG. 11, the surface mount packaged IC device can be mounted to the PCB. A mounting epoxy can be applied to the underbelly of the surface mount packaged IC device before mounting onto the PCB. The PCB can include contact pads to electrically couple with the packaged IC device via the plurality of leads (for example, the source leads 720A, 720B, a sense lead 722, a gate lead 724, a Kelvin source lead 726, and drain leads 740A, 740B). The slots 820 (for example, slots 820A-820F, as illustrated in FIG. 8B) can provide a continuous load path through the lead frame, which can reduce the chances of and/or prevent delamination of the lead frame from molding material when under thermal stress.

### Additional Embodiments

In the foregoing specification, the disclosure has been described with reference to specific embodiments. It will, however, be evident that various modifications and changes may be made thereto without departing from the broader spirit and scope of the disclosure. The specification and drawings are, accordingly, to be regarded in an illustrative rather than restrictive sense.

Indeed, although this disclosure is in the context of certain embodiments and examples, it will be understood by those skilled in the art that the inventions extend beyond the specifically disclosed embodiments to other alternative embodiments and/or uses of the inventions and equivalents thereof. In addition, while several variations of the embodiments have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments disclosed herein. Any methods disclosed herein need not be performed in the order recited. Thus, it is intended that the scope of the disclosure should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the disclosure is not to be limited to the particular forms or methods disclosed, but, to the contrary, the disclosure is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A semiconductor package with a dual sided heat dissipation structure, the semiconductor package comprising:
a semiconductor die having a first side and a second side, the second side being opposite to the first side;
a heat spreader on the first side of the semiconductor die;
a lead frame on the second side of the semiconductor die; and
a die clip positioned between the semiconductor die and a portion of the lead frame, wherein the die clip and the lead frame are joined at connection points.

2. The semiconductor package of claim 1, wherein the die clip comprises openings at the connection points.

3. The semiconductor package of claim 1, wherein the lead frame comprises a gate lead and a Kelvin source lead, a first connection point of the connection points joins the die clip and the gate lead, and a second connection point of the connection points joins the die clip and the Kelvin source lead.

4. The semiconductor package of claim 1, wherein the semiconductor package is free from solder between the lead frame and the die clip.

5. The semiconductor package of claim 1, wherein the connection points provide alignment points between the lead frame and the die clip for welding the die clip and the lead frame.

6. The semiconductor package of claim 1, wherein the semiconductor die comprises a field effect transistor, wherein the lead frame comprises electrical contact points to terminals of the semiconductor die, and wherein the terminals of the semiconductor die comprise a source terminal, a gate terminal, a Kelvin source terminal, and a drain terminal.

7. The semiconductor package of claim 6, wherein a first side of the lead frame comprises a plurality of leads, and wherein the plurality of leads comprises:
two source leads connected to the source terminal of the semiconductor die;
a gate lead connected to the gate terminal of the semiconductor die; and
a Kelvin source lead connected to the Kelvin source terminal of the semiconductor die, wherein the gate lead and the Kelvin source lead are positioned between the two gate leads.

8. The semiconductor package of claim 7, wherein a second side of the lead frame opposite to the first side of the lead frame comprises one or more drain leads electrically connected to the drain terminal of the semiconductor die.

9. The semiconductor package of claim 7, further comprising a sensing lead on the first side of the lead frame, the sensing lead positioned between the two source leads.

10. The semiconductor package of claim 1, wherein the lead frame comprises a lead, and at least a portion of the lead that extends beyond the heat spreader is flat.

11. The semiconductor package of claim 1, further comprising a thermistor die, wherein the lead frame comprises a thermistor lead electrically connected to a terminal of the thermistor die.

12. The semiconductor package of claim 1, further comprising die attach solder positioned between the heat spreader and the first side of the semiconductor die.

13. The semiconductor package of claim 1, wherein the heat spreader is electrically connected to a drain terminal of the semiconductor die.

14. The semiconductor package of claim 1, wherein the die clip is positioned within a footprint of the lead frame.

15. A method of assembling a semiconductor package, the method comprising:
joining a die clip with a lead frame at a plurality of connection points; and
after the joining, soldering the die clip to a semiconductor die,
wherein the die clip and the lead frame are on an opposite side of the semiconductor die than a heat spreader after the soldering.

16. The method of claim 15, wherein the joining comprises welding.

17. The method of claim 15, wherein the semiconductor die comprises a field effect transistor, and the lead frame comprises a gate lead and a Kelvin source lead.

18. The method of claim 15, wherein the die clip comprises a plurality of openings at the connection points.

19. The method of claim 15, further comprising reflowing solder to connect the heat spreader and the semiconductor die prior to the soldering.

20. The method of claim 15, further comprising pre-molding the heat spreader prior to the soldering.
